(19) United States
(12) Patent Application Publication
(10) Pub. No.: US 2007/0044834 A1
(43) Pub. Date: Mar. 1, 2007

(54) CIGS photovoltaic cells

(76) Inventors: Howard Berke, Hollis, NH (US); Russell Gaudiana, Merrimack, NH (US)

Correspondence Address: FISH & RICHARDSON PC, P.O. BOX 1022, MINNEAPOLIS, MN, 55440-1022, US

(21) Appl. No.: 11/487,276

(22) Filed: Jul. 14, 2006

Related U.S. Application Data
(60) Provisional application No. 60/699,114, filed on Jul. 14, 2005.

(51) Int. Cl. H01L 31/00

(52) U.S. Cl. 136/262; 136/264

(57) ABSTRACT

CIGS photovoltaic cells, as well as related components, systems, and methods, are disclosed.

### CROSS REFERENCE TO RELATED APPLICATION

This application claims priority to U.S. Provisional Application Ser. No. 60/699,114, filed Jul. 14, 2005, the contents of which are hereby incorporated by reference.

### TECHNICAL FIELD

This disclosure relates to CIGS photovoltaic cells, as well as related components, systems, and methods.

### BACKGROUND

Photovoltaic cells can be used to convert solar energy to electrical energy. Such cells generally include a photoactive layer disposed between two electrodes. Generally, light passes through one or both of the electrodes to interact with the photoactive layer to convert solar energy to electrical energy.

### SUMMARY

In one aspect, the invention features a method that includes contacting a die with a first layer, the first layer supporting a first material containing copper indium gallium selenide (CuInGaSe₂; CIGS), so that at least a portion of the first material is transferred to a second layer.

In another aspect, the invention features a method that includes disposing a material containing CIGS on a metal foil, transferring the metal foil to a first substrate, and configuring the material, the metal foil, and the first substrate to form a photovoltaic cell.

In another aspect, the invention features an article that includes a mesh electrode, and a first layer containing CIGS supported by the mesh electrode, in which the article is a photovoltaic cell.

In still another aspect, the invention features an article that includes first and second transparent electrodes; and a first layer containing CIGS between the first and second electrodes; in which the article is a photovoltaic cell.

Embodiments can include one or more of the following aspects.

The method can further include heating the die to at least about 550° C. (e.g., at least about 650° C.).

The contacting can include applying a pressure of at least about 100 psi (e.g., at least about 1,000 psi, at least about 5,000 psi) to the die.

The method can further include disposing a release layer between the first material and the first layer. The release layer can include a second material with a melting point at least about 550° C. In some embodiments, the release layer can include a metal.

The first material can be attached to the second layer through an adhesive layer on the second layer. In some embodiments, the adhesive layer includes epoxies, polyurethanes, polyureas, styrene-acrylonitrile copolymers, polyethylene-based polymers, or polypropylene-based polymers.

The first material can be disposed on the first layer by vacuum coating or solution coating.

The die can contact the first layer at a surface on the die, at least a portion of which is curved.

The second layer can receive the first material at a surface on the second layer, at least a portion of which is curved.

The first layer can include a metal, such as molybdenum, titanium, or stainless steel.

The first or second layer can include a polymer selected from the group consisting of polyethylene terephthalates, polyimides, polyethylene naphthalates, polymeric hydrocarbons, cellulosic polymers, polycarbonates, polyamides, polyethers, polyether ketones, and combinations thereof.

The first or second layer can include a flexible substrate.

The first and second layer can include a transparent substrate.

The method can further include configuring the first material and the second layer to form a photovoltaic cell. In some embodiments, a photovoltaic cell can be formed by disposing the first material and a metal foil between two substrates.

The mesh electrode or at least one of the first and second transparent substrates can be supported by a substrate (e.g., a flexible substrate). The substrate can include a polymer selected from the group consisting of polyethylene terephthalates, polyimides, polyethylene naphthalates, polymeric hydrocarbons, cellulosic polymers, polycarbonates, polyamides, polyethers, polyether ketones, and combinations thereof.

The layer containing CIGS can be supported by the mesh electrode or at least one of the first and second transparent electrodes through an adhesive layer.

Embodiments can provide one or more of the following advantages.

The CIGS photovoltaic cells formed by the stamping methods described herein do not need to contain a molybdenum layer, which is a non-transparent electrode used to support the CIGS layer in conventional CIGS photovoltaic cells.

In some embodiments, the methods described herein allows the preparation of CIGS photovoltaic cells with two transparent electrodes, thereby permitting an increased light absorption by the cells.

Other features, objects, and advantages of the invention will be apparent from the description and drawings, and from the claims.

### DESCRIPTION OF DRAWINGS

FIG. 1 is a schematic representation of a hot stamping process of transferring a CIGS layer to a flat substrate;

FIG. 2 is a cross-sectional view of a CIGS layer attached to a flat substrate;

FIG. 3 is a schematic representation of a hot stamping process of transferring a CIGS layer to a curved substrate;

FIG. 4 is a cross-sectional view of a curved CIGS layer attached to a curved substrate;

FIG. 5 is a cross-sectional view of a CIGS photovoltaic cell;

FIG. 6 is an elevational view of an embodiment of a mesh electrode;

FIG. 7 is a cross-sectional view of the mesh electrode of FIG. 6;

FIG. 8 is a cross-sectional view of a portion of a mesh electrode;

FIG. 9 is a cross-sectional view of another CIGS photovoltaic cell;

FIG. 10 is a schematic of a system containing multiple photovoltaic cells electrically connected in series; and

FIG. 11 is a schematic of a system containing multiple photovoltaic cells electrically connected in parallel.

Like reference symbols in the various drawings indicate like elements.

### DETAILED DESCRIPTION

In general, this disclosure relates to methods of transferring a CIGS layer to a substrate for preparing a photovoltaic cell.

In some embodiments, a CIGS layer can be prepared and transferred to a substrate by the following method:

First, a CIGS layer can be formed on a first layer. In some embodiments, the first layer can include a metal foil or a polymeric substrate and a metal layer supported by the polymeric substrate. Examples of metals that can be used to prepare the metal foil or the metal layer include molybdenum, titanium, and stainless steel. Examples of polymers that can be used to prepare the polymeric substrate include polyethylene terephthalates, polyimides, polyethylene naphthalates, polymeric hydrocarbons, cellulosic polymers, polycarbonates, polyamides, polyethers, polyether ketones, and combinations thereof. Preferably, the polymeric substrate is formed of a polymer with a high decomposition temperature (e.g., at least about 550° C. or at least about 600° C.), such as a polyimide. The metal layer can be disposed onto the polymeric substrate by a suitable method, such as sputter deposition.

In some embodiments, the CIGS layer can be formed by coating CIGS precursors (e.g., oxides of Cu, In, and Ga) on the first layer using, for example, vacuum deposition or a solution coating process. For example, an aqueous solution of nanoparticles of Cu, In, and Ga oxides can be coated on the first layer. The CIGS precursors can then be dried and reduced by hydrogen gas to form a metal alloy layer. The metal alloy layer can subsequently be annealed in H₂Se to form a CIGS layer on the first layer. In some embodiments, the annealing temperature does not exceed the decomposition temperature or melting point of a polymeric substrate. In some embodiments, the annealing temperature is at most about 500° C.

After the CIGS layer is formed, it can be transferred by a stamping method to a second layer with an electrode formed thereon. As an example, a surface (e.g., a curved surface) of a die (e.g., a hot stamping die) can be brought into contact with the back surface of the first layer (e.g., a metal foil or a flexible polymeric substrate with a metal layer). The front surface of the first layer, which has a CIGS layer, can then be brought into contact with the second layer, which serves as a receiving layer. When a pressure is applied to the die, the CIGS layer on the front surface of the first layer transfers and adheres to the second layer. The pressure applied to the die can be at least about 100 psi (e.g., at least about 1,000 psi, at least about 5,000 psi). In some embodiments, the front surface of the first layer can be brought into contact with the second layer before the die contacts the back surface of the first layer. In these embodiments, the CIGS layer can be adhered to the second layer before being detached from the first layer.

After the CIGS layer is transferred to the second layer, another electrode and substrate can be sequentially disposed on top of the CIGS layer by conventional methods to form one or more photovoltaic cells. The photovoltaic cells thus formed do not contain the metal foil or metal layer (which typically is non-transparent) used in the first layer as an electrode. Thus, the methods described above allows the preparation of photovoltaic cells with two transparent electrodes, thereby permitting an increased light absorption by the cells. In some embodiments, the electrodes in the photovoltaic cells thus formed can vary as desired, including mesh or non-mesh electrodes, transparent or non-transparent electrodes, conductive or semiconductive electrodes, and metal or metal oxides electrodes.

The second layer can include a polymeric substrate. Examples of the polymers that can be used to prepare the polymeric substrate include polyethylene terephthalates, polyimides, polyethylene naphthalates, polymeric hydrocarbons, cellulosic polymers, polycarbonates, polyamides, polyethers, polyether ketones, and combinations thereof.

In some embodiments, the die can be heated to a suitable temperature (e.g., at least about 550° C., at least about 600° C., at least about 650° C.) to facilitate transfer of the CIGS layer from the front surface of the first layer to the second layer.

In some embodiments, a release layer can be included between the CIGS layer and the first layer to aid release of the CIGS layer. In some embodiments, when a release layer is present, the CIGS layer is formed on the release layer, which in turn is formed on the first layer. The release layer can be coated on the first layer by methods known in the art.

In some embodiments, the release layer can include a material that softens or melts at or below the temperature of the die during the stamping process, but does not soften or melt at the annealing temperature during the preparation of the CIGS layer. For example, the release layer can include a material with a melting point at least about 550° C. Examples of the materials that can be used to prepare the release layer include a metal (such as a metal having a melting point at least about 550°). The release layer can have a thickness at least about 0.1 micron (at least about 0.5 micron, at least about 1.0 micron) or at most about 50 microns (at most about 10 microns, at most about 5 microns). In some embodiments, the release layer softens or melts during the stamping process to facilitate the detachment of the CIGS layer from the first layer. The CIGS layer can be detached at the top, at the bottom, or at a place between the top and the bottom of the release layer.

In some embodiments, an adhesive layer can be disposed on the second layer to facilitate the attachment of the CIGS layer to the second layer. The adhesive layer can have a thickness at least about 0.1 micron (at least about 0.5 micron, at least about 1.0 micron) or at most about 50 microns (at most about 10 microns, at most about 5 microns). In general, any adhesive material capable of holding the CIGS layer in place can be used in the adhesive layer. In some embodiments, the adhesive material is a heat-sensitive adhesive material, i.e., a material that becomes adhesive after being heated at a certain activation temperature (e.g., at most about 300° C., at most about 250° C., at most about 200° C., at most about 150° C., at most about 100° C., or at most about 50° C.). Preferably, the activation temperature is lower than the temperature of the die used during the stamping process. Examples of heat-sensitive adhesive materials include epoxies, polyurethanes, polyureas, styrene-acrylonitrile copolymers, polyethylene-based polymers, or polypropylene-based polymers. Without wishing to be bound by theory, it is believed that the adhesive layer can facilitate the adhering of the CIGS layer with the second layer. For example, when the die is heated during the stamping process, a heat-sensitive adhesive material in the adhesive layer becomes adhesive and then adheres the CIGS layer to the second layer. In some embodiments, the adhesive material can include a fluorinated adhesive. The adhesive material can also be formed of a material that is transparent at the thickness used or can contain an electrically conductive adhesive.

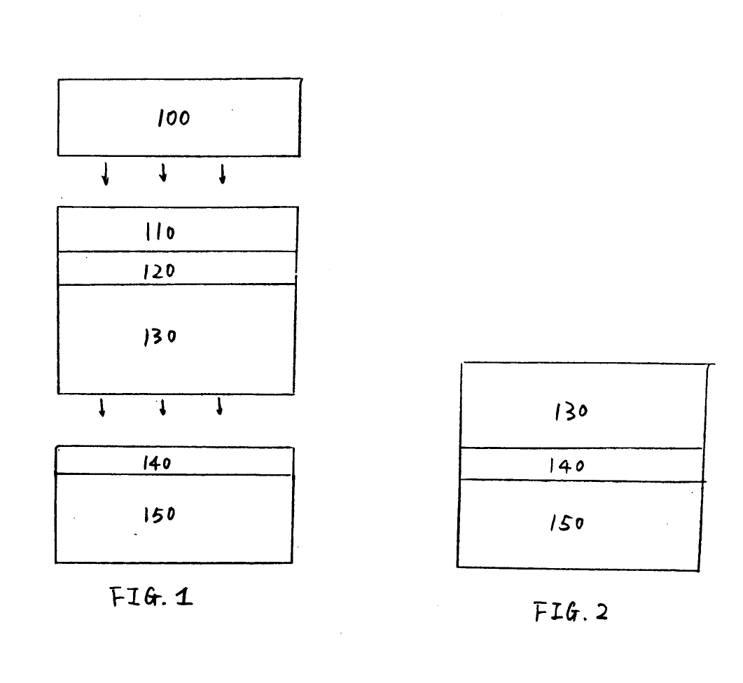

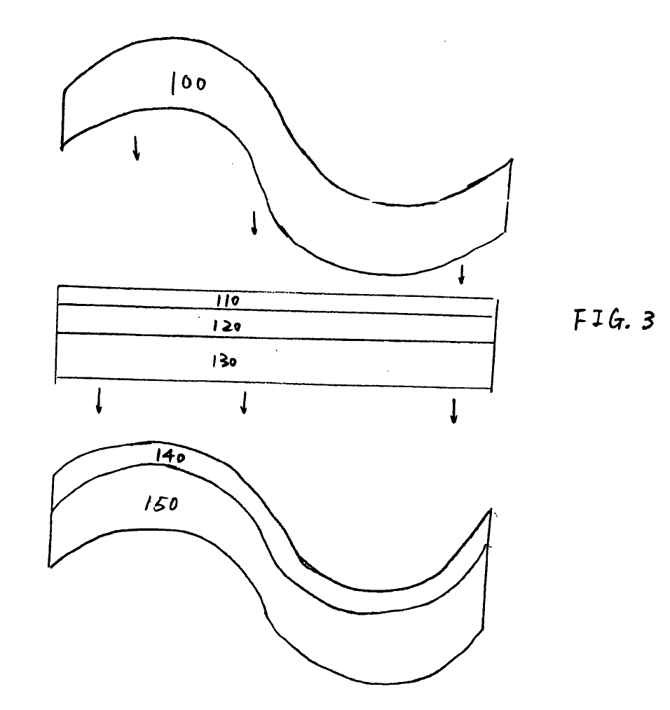

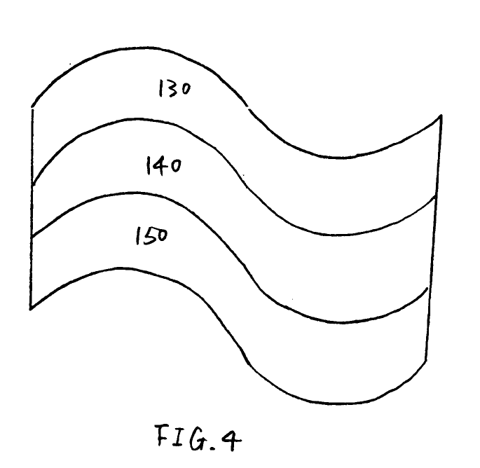

FIG. 1 is a schematic representation of a hot stamping process of transferring a CIGS layer 130 from a flat substrate 110 to a flat receiving substrate 150 by using a die 100. Substrate 110 can be a metal foil or a polymeric substrate with a metal layer formed thereon. Substrate 150 can be a polymeric substrate. As shown in FIG. 1, a release layer 120 is formed between CIGS layer 130 and flat substrate 110 and an adhesive layer 140 is formed on substrate 150. During the hot stamping process, die 100 is heated to a suitable temperature (e.g., at least about 550° C.) and then brought into contact with substrate 110. After release layer 120 softens or melts, pressure (e.g., at least about 100 psi) is applied to die 100 to bring CIGS layer 130 into contact with adhesive layer 140 so that it is adhered to substrate 150. CIGS layer 130 can then be detached at release layer 120 from substrate 110 when die 100 is removed. FIG. 2 shows a cross-sectional view of CIGS layer 130 attached to substrate 150 through adhesive layer 140. FIG. 3 shows a similar process to that described in FIG. 1 except that both substrates 110 and 150 have curved surfaces. FIG. 4 shows a cross-sectional view of CIGS layer 130 that is attached to substrate 150 through adhesive layer 140 and conforms to curved surface of substrate 150.

In certain embodiments, a CIGS layer can be prepared and transferred to a substrate by the following method. First, the CIGS layer can be formed on a first layer by the methods described above (e.g., via a solution coating process using CIGS precursors). The first layer can include a metal foil or a metal layer supported by a polymeric substrate. The CIGS layer and the first layer together can then be cut into any desired shapes (e.g., ribbons) and mounted onto a second layer having an electrode and adhesive formed thereon. A polymeric filler can be placed on the open areas of the CIGS layer. Another electrode and substrate can be sequentially disposed on top of the CIGS layer by conventional methods to form one or more photovoltaic cells.

In some embodiments, the methods described above can be used in a continuous manufacturing process, such as roll-to-roll or web processes. Examples of roll-to-roll processes have been described in, for example, U.S. Application Publication No. 2005-0263179.

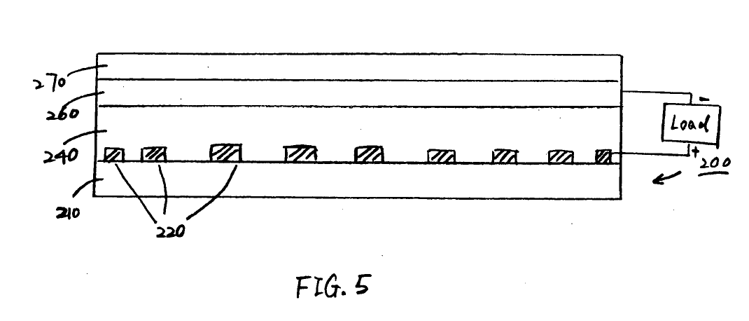

In some embodiments, the methods described above can be used to prepare a CIGS photovoltaic cell. FIG. 5 shows a cross-sectional view of a CIGS photovoltaic cell 200 that includes a transparent substrate 210, a mesh cathode 220, a photoactive layer (containing CIGS) 240, an anode 260, and a substrate 270.

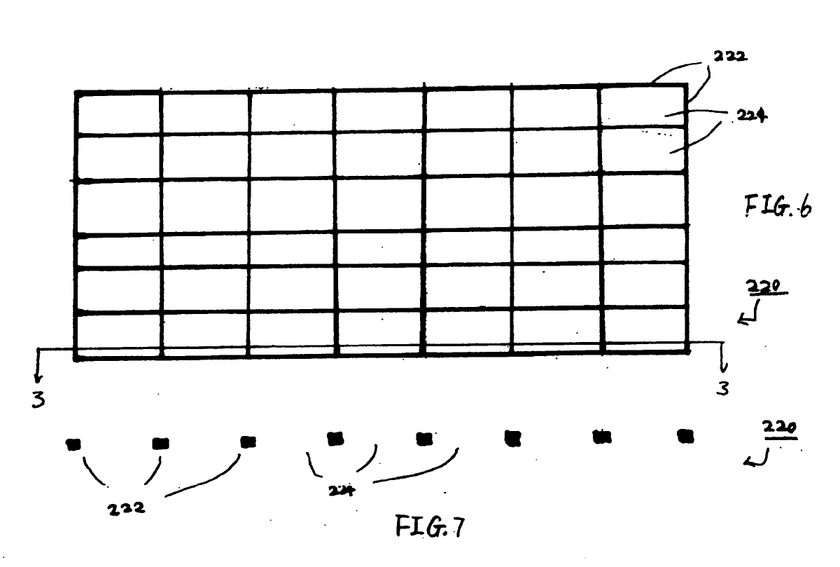

FIGS. 6 and 7 respectively show an elevational view and a cross-sectional of a mesh electrode. As shown in FIGS. 6 and 7, mesh cathode 220 includes solid regions 222 and open regions 224. In general, regions 222 are formed of electrically conducting material so that mesh cathode 220 can allow light to pass therethrough via regions 224 and conduct electrons via regions 222.

The area of mesh cathode 220 occupied by open regions 224 (the open area of mesh cathode 220) can be selected as desired. Generally, the open area of mesh cathode 220 is at least about 10% (e.g., at least about 20%, at least about 30%, at least about 40%, at least about 50%, at least about 60%, at least about 70%, at least about 80%) and/or at most about 99% (e.g., at most about 95%, at most about 90%, at most about 85%) of the total area of mesh cathode 220.

Mesh cathode 220 can be prepared in various ways. In some embodiments, mesh electrode can be stamped onto a layer (e.g., a substrate) as described above. In some embodiments, mesh cathode 220 is a woven mesh formed by weaving wires of material that form solid regions 222. The wires can be woven using, for example, a plain weave, a Dutch, weave, a twill weave, a Dutch twill weave, or combinations thereof. In certain embodiments, mesh cathode 220 is formed of a welded wire mesh. In some embodiments, mesh cathode 220 is an expanded mesh formed. An expanded metal mesh can be prepared, for example, by removing regions 224 (e.g., via laser removal, via chemical etching, via puncturing) from a sheet of material (e.g., an electrically conductive material, such as a metal), followed by stretching the sheet (e.g., stretching the sheet in two dimensions). In certain embodiments, mesh cathode 220 is a metal sheet formed by removing regions 224 (e.g., via laser removal, via chemical etching, via puncturing) without subsequently stretching the sheet.

In certain embodiments, solid regions 222 are formed entirely of an electrically conductive material (e.g., regions 222 are formed of a substantially homogeneous material that is electrically conductive). Examples of electrically conductive materials that can be used in regions 222 include electrically conductive metals, electrically conductive alloys and electrically conductive polymers. Exemplary electrically conductive metals include gold, silver, copper, aluminum, nickel, palladium, platinum and titanium. Exemplary electrically conductive alloys include stainless steel (e.g., 332 stainless steel, 316 stainless steel), alloys of gold, alloys of silver, alloys of copper, alloys of aluminum, alloys of nickel, alloys of palladium, alloys of platinum and alloys of titanium. Exemplary electrically conducting polymers include polythiophenes (e.g., poly(3,4-ethelynedioxythiophene) (PEDOT)), polyanilines (e.g., doped polyanilines), polypyrroles (e.g., doped polypyrroles). In some embodiments, combinations of electrically conductive materials are used. In some embodiments, solid regions 222 can have a resistivity less than about 3 ohm per square.

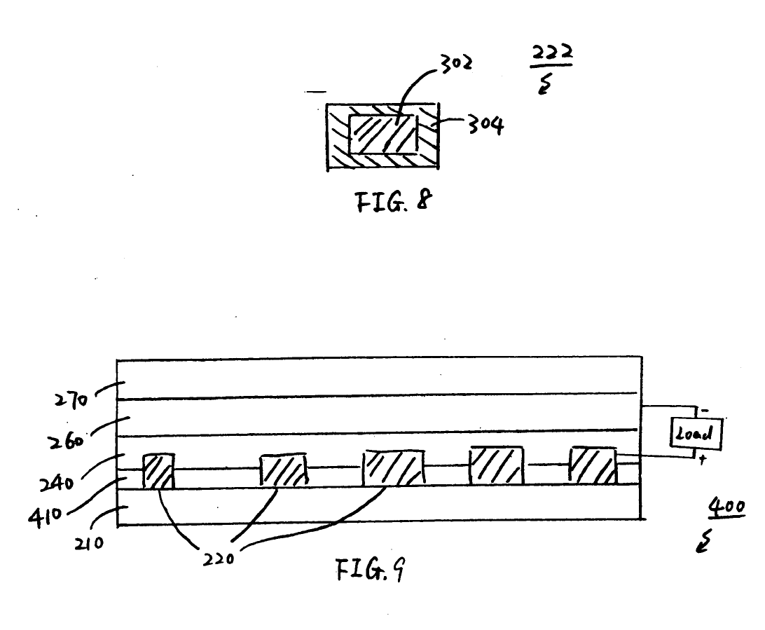

As shown in FIG. 8, in some embodiments, solid regions 222 are formed of a material 302 that is coated with a different material 304 (e.g., using metallization, using vapor deposition). In general, material 302 can be formed of any desired material (e.g., an electrically insulative material, an electrically conductive material, or a semiconductive material), and material 304 is an electrically conductive material. Examples of electrically insulative material from which material 302 can be formed include textiles, optical fiber materials, polymeric materials (e.g., a nylon) and natural materials (e.g., flax, cotton, wool, silk). Examples of electrically conductive materials from which material 302 can be formed include the electrically conductive materials disclosed above. Examples of semiconductive materials from which material 302 can be formed include indium tin oxide, fluorinated tin oxide, tin oxide, and zinc oxide. In some embodiments, material 302 is in the form of a fiber, and material 304 is an electrically conductive material that is coated on material 302. In certain embodiments, material 302 is in the form of a mesh (see discussion above) that, after being formed into a mesh, is coated with material 304. As an example, material 302 can be an expanded metal mesh, and material 304 can be PEDOT that is coated on the expanded metal mesh.

Generally, the maximum thickness of mesh cathode 220 (i.e., the maximum thickness of mesh cathode 220 in a direction substantially perpendicular to the surface of substrate 210 in contact with mesh cathode 220) should be less than the total thickness of photoactive 240. Typically, the maximum thickness of mesh cathode 220 is at least 0.1 micron (e.g., at least about 0.2 micron, at least about 0.3 micron, at least about 0.4 micron, at least about 0.5 micron, at least about 0.6 micron, at least about 0.7 micron, at least about 0.8 micron, at least about 0.9 micron, at least about one micron) and/or at most about 10 microns (e.g., at most about nine microns, at most about eight microns, at most about seven microns, at most about six microns, at most about five microns, at most about four microns, at most about three microns, at most about two microns).

While shown in FIG. 6 as having a rectangular shape, open regions 224 can generally have any desired shape (e.g., square, circle, semicircle, triangle, diamond, ellipse, trapezoid, irregular shape). In some embodiments, different open regions 224 in mesh cathode 220 can have different shapes.

Although shown in FIG. 7 as having square cross-sectional shape, solid regions 222 can generally have any desired shape (e.g., rectangle, circle, semicircle, triangle, diamond, ellipse, trapezoid, irregular shape). In some embodiments, different solid regions 222 in mesh cathode 220 can have different shapes. In embodiments where solid regions 222 have a circular cross-section, the cross-section can have a diameter in the range of about 5 microns to about 200 microns. In embodiments where solid regions 222 have a trapezoid cross-section, the cross-section can have a height in the range of about 0.1 micron to about 5 microns and a width in the range of about 5 microns to about 200 microns.

In some embodiments, mesh cathode 220 is flexible (e.g., sufficiently flexible to be incorporated in photovoltaic cell 200 using a continuous, roll-to-roll manufacturing process). In certain embodiments, mesh cathode 220 is semi-rigid or inflexible. In some embodiments, different regions of mesh cathode 220 can be flexible, semi-rigid or inflexible (e.g., one or more regions flexible and one or more different regions semi-rigid, one or more regions flexible and one or more different regions inflexible).

In general, mesh electrode 220 can be disposed on substrate 210. In some embodiments, mesh electrode 220 can be partially embedded in substrate 210.

Substrate 210 is generally formed of a transparent material. As referred to herein, a transparent material is a material which, at the thickness used in a photovoltaic cell 200, transmits at least about 60% (e.g., at least about 70%, at least about 75%, at least about 80%, at least about 85%, at least about 90%, at least about 95%) of incident light at a wavelength or a range of wavelengths used during operation of the photovoltaic cell. Exemplary materials from which substrate 210 can be formed include polyethylene terephthalates, polyimides, polyethylene naphthalates, polymeric hydrocarbons, cellulosic polymers, polycarbonates, polyamides, polyethers, polyether ketones, and combinations thereof. In certain embodiments, the polymer can be a fluorinated polymer. In some embodiments, combinations of polymeric materials are used. In certain embodiments, different regions of substrate 210 can be formed of different materials.

In general, substrate 210 can be flexible, semi-rigid or rigid (e.g., glass). In some embodiments, substrate 210 has a flexural modulus of less than about 5,000 megaPascals (e.g., less than about 2,500 megapascals or less than about 1,000 megapascals). In certain embodiments, different regions of substrate 210 can be flexible, semi-rigid or inflexible (e.g., one or more regions flexible and one or more different regions semi-rigid, one or more regions flexible and one or more different regions inflexible).

Typically, substrate 210 is at least about one micron (e.g., at least about five microns, at least about 10 microns) thick and/or at most about 1,000 microns (e.g., at most about 500 microns thick, at most about 300 microns thick, at most about 200 microns thick, at most about 100 microns, at most about 50 microns) thick.

Generally, substrate 210 can be colored or non-colored. In some embodiments, one or more portions of substrate 210 is/are colored while one or more different portions of substrate 210 is/are non-colored.

Substrate 210 can have one planar surface (e.g., the surface on which light impinges), two planar surfaces (e.g., the surface on which light impinges and the opposite surface), or no planar surfaces. A non-planar surface of substrate 210 can, for example, be curved or stepped. In some embodiments, a non-planar surface of substrate 210 is patterned (e.g., having patterned steps to form a Fresnel lens, a lenticular lens or a lenticular prism).

Photoactive layer 240 generally contains CIGS. Generally, active layer 240 is sufficiently thick to be relatively efficient at absorbing photons impinging thereon to form corresponding electrons and holes, and sufficiently thin to be relatively efficient at transporting electrode 220 and 240, respectively. In certain embodiments, photoactive layer 240 is at least 0.05 micron (e.g., at least about 0.1 micron, at least about 0.2 micron, at least about 0.3 micron) thick and/or at most about one micron (e.g., at most about 0.5 micron, at most about 0.4 micron) thick. In some embodiments, photoactive layer 240 is from about 0.1 micron to about 0.2 micron thick.

Anode 260 is generally formed of an electrically conductive material, such as one or more of the electrically conductive materials noted above. In some embodiments, anode 260 is formed of a combination of electrically conductive materials.

In general, substrate 270 can be identical to substrate 220. In some embodiments, substrate 270 can be different from substrate 220 (e.g., having a different shape or formed of a different material or a non-transparent material).

FIG. 9 shows a cross-sectional view of a photovoltaic cell 400 that includes an adhesive layer 410 between substrate 210 and photoactive layer 240.

Generally, any material capable of holding mesh cathode 220 in place can be used in adhesive layer 410. In general, adhesive layer 410 is formed of a material that is transparent at the thickness used in photovoltaic cell 400. Examples of adhesives include epoxies and urethanes. Examples of commercially available materials that can be used in adhesive layer 410 include Bynel™ adhesive (DuPont) and 615 adhesive (3M). In some embodiments, layer 410 can include a fluorinated adhesive. In certain embodiments, layer 410 contains an electrically conductive adhesive. An electrically conductive adhesive can be formed of, for example, an inherently electrically conductive polymer, such as the electrically conductive polymers disclosed above (e.g., PEDOT). An electrically conductive adhesive can be also formed of a polymer (e.g., a polymer that is not inherently electrically conductive) that contains one or more electrically conductive materials (e.g., electrically conductive particles). In some embodiments, layer 410 contains an inherently electrically conductive polymer that contains one or more electrically conductive materials.

In some embodiments, the thickness of layer 410 (i.e., the thickness of layer 410 in a direction substantially perpendicular to the surface of substrate 210 in contact with layer 410) is less thick than the maximum thickness of mesh cathode 220. In some embodiments, the thickness of layer 410 is at most about 90% (e.g., at most about 80%, at most about 70%, at most about 60%, at most about 50%, at most about 40%, at most about 30%, at most about 20%) of the maximum thickness of mesh cathode 220. In certain embodiments, however, the thickness of layer 410 is about the same as, or greater than, the maximum thickness of mesh cathode 220.

In general, a photovoltaic cell having a CIGS layer can be manufactured as desired, such as the methods described above.

In some embodiments, mesh cathode 220 is formed by printing the cathode material on the surface of substrate 210 or adhesive layer 410 to provide an electrode having the open structure shown in the figures. For example, mesh cathode 220 can be printed using stamping, dip coating, extrusion coating, spray coating, inkjet printing, screen printing, and gravure printing. The cathode material can be disposed in a paste which solidifies upon heating or radiation (e.g., UV radiation, visible radiation, IR radiation, electron beam radiation). The cathode material can be, for example, vacuum deposited in a mesh pattern through a screen or after deposition it may be patterned by photolithography.

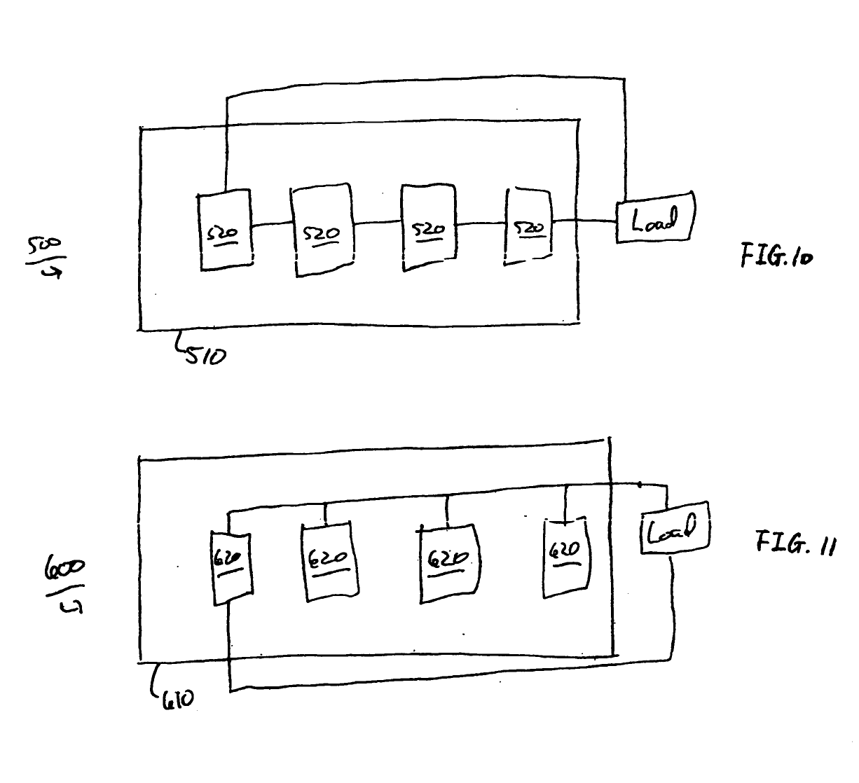

Multiple photovoltaic cells can be electrically connected to form a photovoltaic system. As an example, FIG. 10 is a schematic of a photovoltaic system 500 having a module 510 containing photovoltaic cells 520. Cells 520 are electrically connected in series, and system 500 is electrically connected to a load. As another example, FIG. 11 is a schematic of a photovoltaic system 600 having a module 610 that contains photovoltaic cells 620. Cells 620 are electrically connected in parallel, and system 600 is electrically connected to a load. In some embodiments, some (e.g., all) of the photovoltaic cells in a photovoltaic system can have one or more common substrates. In certain embodiments, some photovoltaic cells in a photovoltaic system are electrically connected in series, and some of the photovoltaic cells in the photovoltaic system are electrically connected in parallel.

In some embodiments, photovoltaic systems containing a plurality of photovoltaic cells can be fabricated using continuous manufacturing processes, such as roll-to-roll or web processes. In some embodiments, a continuous manufacturing process includes: forming a group of photovoltaic cell portions on a first advancing substrate; disposing an electrically insulative material between at least two of the cell portions on the first substrate; embedding a wire in the electrically insulative material between at least two photovoltaic cell portions on the first substrate; forming a group of photovoltaic cell portion on a second advancing substrate; combining the first and second substrates and photovoltaic cell portions to form a plurality of photovoltaic cells, in which at least two photovoltaic cells are electrically connected in series by the wire. In some embodiments, the first and second substrates can be continuously advanced, periodically advanced, or irregularly advanced.

In some embodiments, the stamping methods described above can be used to print a CIGS layer on a substrate for use in a tandem cell. Examples of tandem photovoltaic cells are discussed in U.S. patent application Ser. No. 10/558,878 and U.S. Provisional Application Ser. Nos. 60/790,606, 60/792,635, 60/792,485, 60/793,442, 60/795,103, 60/797,881, and 60/798,258, the contents of which are hereby incorporated by reference.

While certain embodiments have been disclosed, other embodiments are also possible.

As one example, while cathodes formed of mesh have been described, in some embodiments a mesh anode can be used. This can be desirable, for example, when light transmitted by the anode is used. In certain embodiments, both a mesh cathode and a mesh anode are used. This can be desirable, for example, when light transmitted by both the cathode and the anode is used.

As another example, while embodiments have generally been described in which light that is transmitted via the cathode side of the cell is used, in certain embodiments light transmitted by the anode side of the cell is used (e.g., when a mesh anode is used). In some embodiments, light transmitted by both the cathode and anode sides of the cell is used (when a mesh cathode and a mesh anode are used).

As another example, while cathodes formed of mesh have been described, in some embodiments a non-mesh cathode can be used. In certain embodiments, both a non-mesh cathode and a non-mesh anode are used.

As a further example, while electrodes (e.g., mesh electrodes, non-mesh electrodes) have been described as being formed of electrically conductive materials, in some embodiments a photovoltaic cell may include one or more electrodes (e.g., one or more mesh electrodes, one or more non-mesh electrodes) formed of a semiconductive material. Examples of semiconductive materials include indium tin oxide, fluorinated tin oxide, tin oxide, and zinc oxide.

As an additional example, in some embodiments, one or more semiconductive materials can be disposed in the open regions of a mesh electrode (e.g., in the open regions of a mesh cathode, in the open regions of a mesh anode, in the open regions of a mesh cathode and the open regions of a mesh anode). Examples of semiconductive materials include tin oxide, fluorinated tin oxide, tin oxide and zinc oxide. Other semiconductive materials, such as partially transparent semiconductive polymers, can also be disposed in the open regions of a mesh electrode. For example, a partially transparent polymer can be a polymer which, at the thickness used in a photovoltaic cell, transmits at least about 60% (e.g., at least about 70%, at least about 75%, at least about 80%, at least about 85%, at least about 90%, at least about 95%) of incident light at a wavelength or a range of wavelengths used during operation of the photovoltaic cell. Typically, the semiconductive material disposed in an open region of a mesh electrode is transparent at the thickness used in the photovoltaic cell.

As another example, in certain embodiments, a protective layer can be applied to one or both of the substrates. A protective layer can be used to, for example, keep contaminants (e.g., dirt, water, oxygen, chemicals) out of a photovoltaic cell and/or to ruggedize the cell. In certain embodiments, a protective layer can be formed of a polymer (e.g., a fluorinated polymer).

As an additional example, while described as being formed of different materials, in some embodiments materials 302 and 304 are formed of the same material.

As another example, although shown in FIG. 8 as being formed of one material coated on a different material, in some embodiments solid regions 222 can be formed of more than two coated materials (e.g., three coated materials, four coated materials, five coated materials, six coated materials).

Other embodiments are in the claims.

What is claimed is:

1. A method, comprising:
contacting a die with a first layer, the first layer supporting a first material comprising CIGS, so that at least a portion of the first material is transferred to a second layer.

2. The method of claim 1, further comprising heating the die to at least about 550° C.

3. The method of claim 1, further comprising heating the die to at least about 650° C.

4. The method of claim 1, wherein the contacting comprises applying a pressure of at least about 100 psi to the die.

5. The method of claim 1, wherein the contacting comprises applying a pressure of at least about 1,000 psi to the die.

6. The method of claim 1, wherein the contacting comprises applying a pressure of at least about 5,000 psi to the die.

7. The method of claim 1, further comprising disposing a release layer between the first material and the first layer.

8. The method of claim 7, wherein the release layer comprises a second material with a melting point at least about 550° C.

9. The method of claim 7, wherein the release layer comprises a metal.

10. The method of claim 1, wherein the first material is attached to the second layer through an adhesive layer on the second layer.

11. The method of claim 10, wherein the adhesive layer comprises epoxies, polyurethanes, polyureas, styrene-acrylonitrile copolymers, polyethylene-based polymers, or polypropylene-based polymers.

12. The method of claim 1, further comprising disposing the first material on the first layer by vacuum coating or solution coating.

13. The method of claim 1, wherein the die contacts the first layer at a surface on the die, at least a portion of which is curved.

14. The method of claim 1, wherein the second layer receives the first material at a surface on the second layer, at least a portion of which is curved.

15. The method of claim 1, wherein the first or second layer comprises a flexible substrate.

16. The method of claim 1, wherein the first layer comprises a metal.

17. The method of claim 16, wherein the metal comprises molybdenum, titanium, or stainless steel.

18. The method of claim 1, wherein the first or second layer comprises a polymer selected from the group consisting of polyethylene terephthalates, polyimides, polyethylene naphthalates, polymeric hydrocarbons, cellulosic polymers, polycarbonates, polyamides, polyethers, polyether ketones, and combinations thereof.

19. The method of claim 1, wherein the first or second layer comprises a transparent substrate.

20. The method of claim 1, further comprising configuring the first material and the second layer to form a photovoltaic cell.

21. A method, comprising:
disposing a material comprising CIGS on a metal foil;
transferring the metal foil to a first substrate; and
configuring the material, the metal foil, and the first substrate to form a photovoltaic cell.

22. The method of claim 21, wherein the material is disposed on the metal foil by vacuum coating or solution coating.

23. The method of claim 21, wherein the first substrate layer receives the metal foil at a surface on the first substrate, at least a portion of which is curved.

24. The method of claim 21, wherein the configuring comprises disposing the material and the metal foil between the first substrate and a second substrate.

25. The method of claim 24, wherein the first or second substrate is flexible.

26. The method of claim 24, wherein the first or second substrate is transparent.

27. The method of claim 24, wherein the first or second substrate comprises a polymer selected from the group consisting of polyethylene terephthalates, polyimides, polyethylene naphthalates, polymeric hydrocarbons, cellulosic polymers, polycarbonates, polyamides, polyethers, polyether ketones, and combinations thereof.

28. The method of claim 21, wherein the metal foil comprises molybdenum, titanium, or stainless steel.

29. The method of claim 21, wherein the material is attached to the first substrate through an adhesive layer on the first substrate.

30. The method of claim 29, wherein the adhesive layer comprises epoxies, polyurethanes, polyureas, styrene-acrylonitrile copolymers, polyethylene-based polymers, or polypropylene-based polymers.

31. An article, comprising:
a mesh electrode; and
a first layer comprising CIGS supported by the mesh electrode;
wherein the article is a photovoltaic cell.

32. The article of claim 31, wherein the mesh electrode is supported by a substrate.

33. The article of claim 32, wherein the substrate comprises a polymer selected from the group consisting of polyethylene terephthalates, polyimides, polyethylene naphthalates, polymeric hydrocarbons, cellulosic polymers, polycarbonates, polyamides, polyethers, polyether ketones, and combinations thereof.

34. The article of claim 32, wherein the substrate is flexible.

35. The article of claim 31, wherein the first layer is supported by the mesh electrode through an adhesive layer.

36. The article of claim 35, wherein the adhesive layer comprises epoxies, polyurethanes, polyureas, styrene-acrylonitrile copolymers, polyethylene-based polymers, or polypropylene-based polymers.

37. An article, comprising:
first and second transparent electrodes; and
a first layer comprising CIGS between the first and second electrodes;
wherein the article is a photovoltaic cell.

38. The article of claim 37, wherein at least one of the first and second transparent electrodes comprises indium tin oxide.

39. The article of claim 37, wherein at least one of the first and second transparent electrodes is supported by a substrate.

40. The article of claim 39, wherein the substrate comprises a polymer selected from the group consisting of polyethylene terephthalates, polyimides, polyethylene naphthalates, polymeric hydrocarbons, cellulosic polymers, polycarbonates, polyamides, polyethers, polyether ketones, and combinations thereof.

41. The article of claim 39, wherein the substrate is flexible.

42. The article of claim 37, wherein the first layer is attached to at least one of the first and second transparent electrode through an adhesive layer.

43. The article of claim 42, wherein the adhesive layer comprises epoxies, polyurethanes, polyureas, styrene-acrylonitrile copolymers, polyethylene-based polymers, or polypropylene-based polymers.
